(19) United States
(12) Patent Application Publication
(10) Pub. No.: US 2015/0001706 A1
(43) Pub. Date: Jan. 1, 2015

(54) SYSTEMS AND METHODS FOR AVOIDING PROTRUSIONS IN INJECTION MOLDED SOLDER

(71) Applicants: Kabirkumar Mirpuri, Scottsdale, AZ (US); Yoshihiro Tomita, Tsukuba-Shi (JP)

(72) Inventors: Kabirkumar Mirpuri, Scottsdale, AZ (US); Yoshihiro Tomita, Tsukuba-Shi (JP)

(21) Appl. No.: 13/929,087

(22) Filed: Jun. 27, 2013

(51) Int. Cl. H01L 23/00

(52) U.S. Cl. CPC H01L 24/14; H01L 24/11
USPC 257/737; 438/613

(57) ABSTRACT

A method includes positioning a solder mask on an integrated circuit (IC) package substrate with the solder mask having cavities that extend to the IC package substrate, applying molten solder to the flexible solder mask to fill the cavities of the solder mask with solder, and removing the solder mask to expose solder bumps on the IC package substrate. The molten solder includes silver and an additive to reduce formation of a silver compound that causes deformation of solder bumps.

### TECHNICAL FIELD

Embodiments pertain to electronic packaging of integrated circuits. Some embodiments relate to solder bonds for packaged integrated circuits.

### BACKGROUND

Electronic systems often include integrated circuits (ICs) that are connected to a subassembly such as a substrate or motherboard. The ICs can be packaged and inserted into an IC package that is mounted on the subassembly. This is sometimes referred to as second level interconnect (SLI) or higher level. As electronic system designs become more complex, it is a challenge to meet the desired size constraints of the system. One aspect that influences the overall size of a design is the spacing required for the interconnection of the contacts of the IC packages. The IC packages may use ball grid array (BGA) interconnection that attaches solder balls to the IC packages before being bonded into an assembly. As the spacing is reduced, the current methods used to attach solder bumps or passive components to the IC packages becomes more challenging. Thus, there are general needs for devices, systems and methods that address the spacing challenges for contacts of ICs yet provide a robust and cost effective design.

### BRIEF DESCRIPTION OF THE DRAWINGS

FIG. 1 shows an example of a method to form solder bumps while reducing formation of irregularities in the solder bump in accordance with some embodiments;

FIG. 2 illustrates portions of an example of an IMS process;

FIG. 3 shows a block diagram of an example of a device that includes an IC package in accordance with some embodiments.

FIG. 4 is a block diagram of an example of an electronic device 400 incorporating at least one solder and/or method in accordance with at least one embodiment of the invention.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Conventional ball attach processes use either flux or paste to hold the solder balls until a reflow process where the solder balls are attached metallurgically. However, conventional ball attach processes are not able to meet the demands for smaller packaging, such as fine pitch substrates having a pitch of 300 micrometers (300 μm) or less between connections for soldering. Injection molded soldering (IMS) has been developed to allow solder-bump formation with fine pitch package substrates.

In an IMS process, solder bumps are formed using a solder mask. The solder mask is typically formed of a flexible material, such as polyimide. The shape of the solder bumps is determined by the shape of the cavity in the solder mask. The solder bump size can be changed by changing the mask thickness or changing the cavity size. Solder bump pitch is determined from the pitch of the cavities in the solder mask. A problem can occur in solidification of the solder bumps. Protrusions can form in the solder bumps giving the solder bumps an irregular shape. The protrusions may have a needle-like shape or a platelet shape, and can cause gaps in the solder bond of the IC package, or undesired bridging between the solder bonds.

The protrusions are an intermetallic compound (IMC) such as a compound of silver and tin (Ag₃Sn). Analysis has shown that Ag₃Sn IMCs are more likely to form when there is a slow rate of cooling of the molten solder. The process of Ag₃Sn IMC formation can be referred to as nucleation and the protrusions typically occur near the surface of the solder bumps due to the lower temperature at the surface.

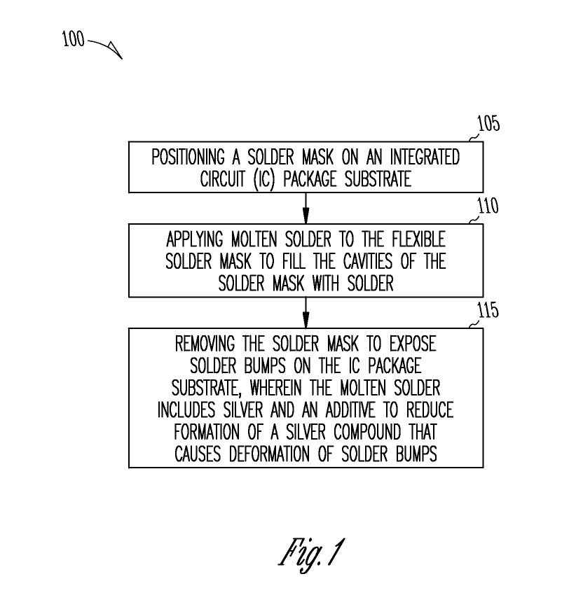

FIG. 1 shows an example of portions of a method 100 to form solder bumps while reducing formation of irregularities in the solder bumps. To reduce the formation of protrusions in the solder bumps, the rate of cooling of the solder bumps is increased so that the solder bumps are at a high temperature for less time. Some examples of increasing the rate of cooling include changing the composition of the solder and using a solder mask that promotes cooling. At block 105, a solder mask is positioned on an IC package substrate. The solder mask can include cavities that extend to the surface IC package substrate where landing pads may have previously been formed.

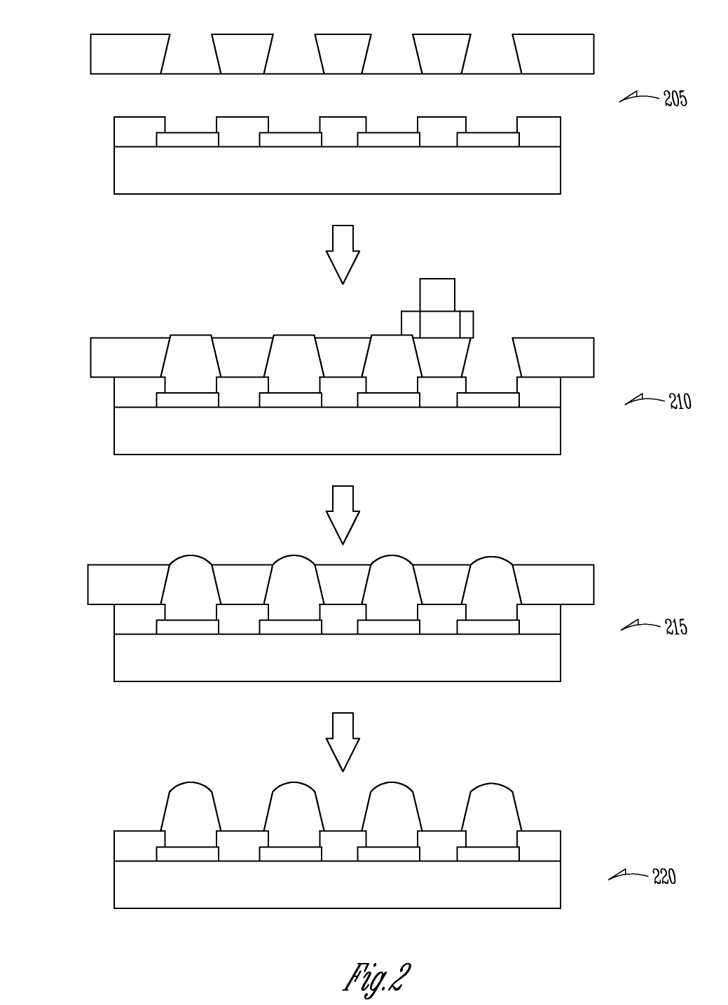

FIG. 2 illustrates portions of an example of an IMS process. The top view 205, illustrates a solder mask positioned on the IC package substrate. Holes can be formed in the solder mask (e.g., by laser drilling) to create apertures of desired size. These cavities in the solder mask can be formed to align with rows of connection pads on the IC package substrate.

Returning to FIG. 1 at block 110, molten solder is applied to the flexible solder mask to fill the cavities of the solder mask with solder. FIG. 2 shows in view 210 that a swipe is made over the solder mask and IC package substrate with a solder “squeeze” filled with molten solder to fill the cavities of the solder mask positioned over the connection pads. As the squeeze moves along during the swipe, molten solder is applied to the mask and flows into the cavities within a row of the mask and the squeeze advances to the next row of cavities to fill the next row with molten solder. Because the squeeze takes time to travel across the substrate, the solder in the cavities remains hot for a period sufficient to cause formation of IMCs. In IMS processes, the solder may include silver (Ag), tin (Sn) and Copper (Cu) and an IMC may be a silver compound. The molten solder includes an additive to reduce formation of the silver compound that causes deformation of solder bumps. In some examples, the molten solder includes an additive to reduce formation of a silver-tin compound (e.g., Ag₃Sn). In view 215 of FIG. 2, the molten solder is allowed to solidify by cooling within the flexible solder mask.

In FIG. 1 at block 115, the solder mask is removed to expose solder bumps on the IC package substrate. This is shown in view 220 of FIG. 2. The solder bumps formed may have a pitch of 300 μm or less. In some examples, the resulting solder bumps have a pitch of 150 μm or less. In some examples, the resulting solder bumps have a height of 80 μm or less.

In some examples, the solder additive decreases undercooling of the molten solder (or increases the rate of cooling) to provide an increased solidification temperature of the molten solder and reduce formation of the silver compound. In certain examples, the additive is a nucleating agent. In some examples, the additive includes zinc. In certain examples, the additive includes a zinc concentration in a range of two to five percent by weight (2-5 wt %). In certain examples, the additive includes a zinc concentration of 3 wt %. In some examples, the additive includes iron (Fe). In certain examples, the additive includes an iron concentration of 0.3 wt %. In certain examples, the molten solder includes a nucleating agent to retard the formation of IMCs. Instead of, or in addition to, raising the solidification temperature, adding an anti-nucleating agent may delay formation of the IMCs until the solder reaches a solidification temperature.

As explained previously, it is desirable to increase the rate of cooling of the solder to prevent the protrusions from forming in the solder balls. The rate of cooling of the solder bumps may be slowed by the material of the solder mask. The solder can include an additive that increases the rate of cooling of the solder. In some examples, the solder mask is a metallic mask (e.g., titanium). The metallic mask may increase dissipation of heat and help to cool the solder faster; thereby reducing the precipitation of IMCs. Also typical masks used in IMS (e.g., polyimide) have tendency to warp, which can also lead to deformations in solder bumps. In addition to enhancing cooling, titanium or a similar material will have lower warpage leading to fewer deformities in the solder bumps.

In some examples, the method 100 of FIG. 1 includes including arranging an IC on the IC package substrate. The solder bumps provide electrical continuity between connection pads of the IC and land pads of the IC substrate. In some examples, the method 100 includes arranging the IC on a first package substrate and arranging a second IC package substrate above the IC. Thus, the IC includes landing pads on the both the top surface of the IC and the bottom surface of the IC for bonding to two separate package substrates. The method further includes forming solder bumps on both the first and second IC package substrates. The solder bumps include the additive to reduce formation of a silver compound that causes deformation of the solder bumps.

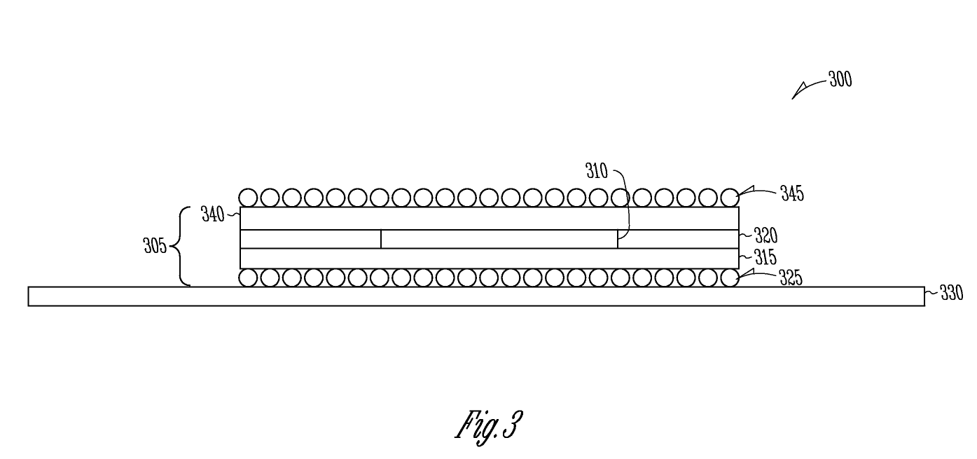

FIG. 3 shows a block diagram of an example of a device 300 that includes an IC package 305. The IC package 305 includes an IC 310 and a first IC package substrate 315 with the IC 310 bonded to the first IC package substrate 315. The IC package 305 may also include a mold material 320 (e.g., a polymer) to encase the IC 310. The IC package 305 includes a plurality of solder bumps 325 formed on the first IC package substrate 315 to provide electrical continuity to connection pads of the IC 310. The solder bumps 325 may have a pitch spacing of 300 μm or less. The solder of a solder bump may include silver and an additive to reduce formation of a silver compound that causes deformation of solder bumps. The additive may include any of the additives and/or agents described previously herein.

The device 300 may be included in a system that includes a printed circuit board 330 (PCB). The IC package substrate 315 may be bonded to the PCB using a plurality of solder connections, and the solder connections have the pitch spacing of the solder bumps (e.g., 300 μm or less). In some examples, the IC package 305 includes a second IC package substrate (340) arranged above the IC 310. A second IC package (not shown) containing a second IC may be arranged above the IC package 305 shown and bonded to the second IC package substrate (340) using solder bumps (345) to create a three-dimensional IC packaging solution.

The methods, systems and devices described minimize formation of protrusions in the solder bumps created by an injection molded solder process. This allows an injection molded solder process to reliably meet the packaging goals of fine-pitch IC packaging.

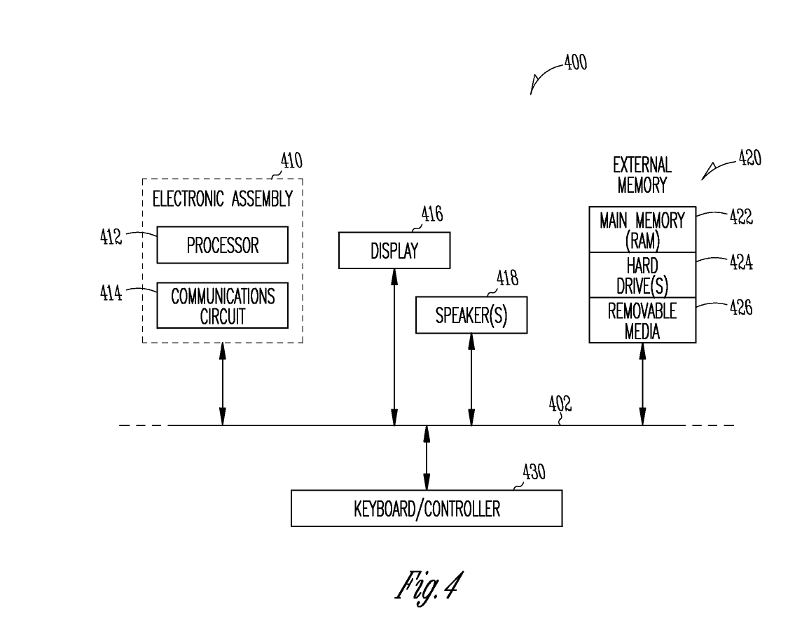

An example of an electronic device using semiconductor chip assemblies and solders as described in the present disclosure is included to show an example of a higher level device application for the present invention. FIG. 4 is a block diagram of an example of an electronic device 400 incorporating at least one solder and/or method in accordance with at least one embodiment of the invention. Electronic device 400 is merely one example of an electronic system in which embodiments of the present invention can be used. Examples of electronic devices 400 include, but are not limited to personal computers, tablet computers, mobile telephones, game devices, MP3 or other digital music players, etc. In this example, electronic device 400 comprises a data processing system that includes a system bus 402 to couple the various components of the system. System bus 402 provides communications links among the various components of the electronic device 400 and can be implemented as a single bus, as a combination of busses, or in any other suitable manner.

An electronic assembly 410 is coupled to system bus 402. The electronic assembly 410 can include any circuit or combination of circuits. In one embodiment, the electronic assembly 410 includes a processor 412 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 410 are a custom circuit, an application-specific integrated circuit (ASIC), or the like, such as, for example, one or more circuits (such as a communications circuit 414) for use in wireless devices like mobile telephones, personal data assistants, portable computers, two-way radios, and similar electronic systems. The IC can perform any other type of function.

The electronic device 400 can also include an external memory 420, which in turn can include one or more memory elements suitable to the particular application, such as a main memory 422 in the form of random access memory (RAM), one or more hard drives 424, and/or one or more drives that handle removable media 426 such as compact disks (CD), flash memory cards, digital video disk (DVD), and the like.

The electronic device 400 can also include a display device 416, one or more speakers 418, and a keyboard and/or controller 430, which can include a mouse, trackball, touch screen, voice-recognition device, or any other device that permits a system user to input information into and receive information from the electronic device 400.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

### ADDITIONAL EXAMPLES

To better illustrate the methods and apparatuses disclosed herein, a non-limiting list of examples is provided below.

Example 1 can include subject matter (such as a method, means for performing acts, or a machine readable medium that can cause the machine to perform acts) including positioning a solder mask on an integrated circuit (IC) package substrate, wherein the solder mask includes cavities that extend to the IC package substrate, applying molten solder to the flexible solder mask to fill the cavities of the solder mask with solder, and removing the solder mask to expose solder bumps on the IC package substrate, wherein the molten solder includes silver and an additive to reduce formation of a silver compound that causes deformation of solder bumps, and wherein the solder bumps have a pitch of 300 micrometers (300 μm) or less.

In Example 2, the subject matter of Example 1 optionally includes applying molten solder that includes an additive that includes zinc to reduce formation of a silver compound.

In Example 3, the subject matter of one or any combination of Examples 1 and 2 optionally includes applying molten solder having a zinc concentration in a range of 2-5 wt %.

In Example 4, the subject matter of one or any combination of Examples 1-3 optionally includes applying molten solder having an iron concentration of 0.3 wt %.

In Example 5, the subject matter of one or any combination of Examples 1-4 optionally includes applying molten solder having a nucleating agent as the additive to reduce formation of a silver compound.

In Example 6, the subject matter of one or any combination of Examples 1-5 optionally includes applying molten solder that includes tin and an additive to reduce formation of a silver-tin compound.

In Example 7, the subject matter of one or any combination of Examples 1-6 optionally includes applying molten solder having an additive that decreases undercooling to provide an increased solidification temperature of the molten solder and reduces formation of the silver compound.

In Example 8, the subject matter of one or any combination of Examples 1-7 optionally includes positioning a metallic mask on the IC package substrate.

In Example 9, the subject matter of one or any combination of Examples 1-8 optionally includes arranging an IC on the IC package substrate, wherein the solder bumps provide electrical continuity to connection pads of the IC.

In Example 10, the subject matter or one or any combination of Examples 1-9 optionally includes arranging an IC on a first IC package substrate and arranging a second IC package substrate above the IC. The method further optionally includes forming solder bumps on both the first and second IC package substrates, wherein the solder bumps include the additive to reduce formation of a silver compound that causes deformation of the solder bumps.

Example 11 can include subject matter, or can optionally be combined with one or any combination of Examples 1-10 to include subject matter (such as an apparatus), including an IC, an IC package including a first IC package substrate and the IC bonded to the first IC package substrate, a plurality of solder bumps formed on the first IC package substrate to provide electrical continuity to connection pads of the IC, wherein the solder bumps have a pitch spacing of 300 μm or less, and wherein solder of a solder bump includes silver and an additive to reduce formation of a silver compound that causes deformation of the solder bump.

In Example 12, the subject matter of Example 11 can optionally include solder including a zinc concentration in a range of 2-5 wt % as the additive to reduce formation of a silver compound.

In Example 13, the subject matter of one or any combination of Examples 11 and 12 can optionally include solder including an iron concentration of 3 wt % as the additive to reduce formation of a silver compound.

In Example 14, the subject matter of one or any combination of Examples 11-13 optionally includes solder including a nucleation agent as the additive to reduce formation of a silver compound.

In Example 15, the subject matter of one or any combination of Examples 11-14 optionally includes solder including tin and an additive to reduce formation of a silver-tin compound.

In Example 16, the subject matter of one or any combination of Examples 11-15 optionally includes solder including an additive that increases a solidifying temperature of molten solder and reduces formation of a silver compound during cooling of the molten solder.

In Example 17, the subject matter of one or any combination of Examples 11-16 optionally includes a second IC package substrate. The IC is optionally bonded to a top surface of the first IC package substrate and a bottom surface of the second IC package substrate, and the plurality of solder bumps may be arranged on a bottom surface of the first IC package substrate and a top surface of the second IC package substrate.

Example 18 can include subject matter, or can optionally be combined with one or any combination of Examples 1-17 to include subject matter (such as a system), including an IC, a printed circuit board (PCB), and IC package that includes an IC package substrate. The IC is bonded to the IC package substrate and the IC package substrate is bonded to the PCB using a plurality of solder connections. The solder connections may have a pitch spacing of 300 μm or less, wherein the solder of a solder connection includes silver and an additive to reduce formation of a silver compound that causes deformation of the solder bump

In Example 19, the subject matter of Example 18 optionally includes solder including zinc as the additive to reduce formation of a silver compound.

In Example 20, the subject matter of one or any combination of Examples 18 and 19 optionally includes solder including a nucleating agent as the additive to reduce formation of a silver compound.

In Example 21, the subject matter of one or any combination of Examples 18-20 optionally includes solder including an additive that decreases undercooling to provide an increased solidification temperature of the molten solder and reduces formation of the silver compound.

Example 22 can include subject matter, or can optionally be combined with any portion or combination of any portions of any one or more of Examples 1 through 21 to include subject matter, that can include means for performing any one or more of the functions of Examples 1 through 21, or a machine-readable medium including instructions that, when performed by a machine, cause the machine to perform any one or more of the functions of Examples 1 through 21.

Each of these non-limiting examples can stand on its own, or can be combined in various permutations or combinations with one or more of the other examples.

What is claimed is:

1. A method comprising:
positioning a solder mask on an integrated circuit (IC) package substrate, wherein the solder mask includes cavities that extend to the IC package substrate;
applying molten solder to the flexible solder mask to fill the cavities of the solder mask with solder; and
removing the solder mask to expose solder bumps on the IC package substrate, wherein the molten solder includes silver and an additive to reduce formation of a silver compound that causes deformation of solder bumps, and wherein the solder bumps have a pitch of 300 micrometers (300 μm) or less.

2. The method of claim 1, wherein applying molten solder includes applying molten solder that includes an additive that includes zinc to reduce formation of a silver compound.

3. The method of claim 1, wherein applying molten solder includes applying molten solder having a zinc concentration in a range of two to five percent by weight (2-5 wt %).

4. The method of claim 1, wherein applying molten solder further includes applying molten solder having an iron concentration of 0.3 percent by weight (0.3 wt %).

5. The method of claim 1, wherein applying molten solder further includes applying molten solder that includes tin and an additive to reduce formation of a silver-tin compound.

6. The method of claim 1, wherein applying molten solder further includes applying molten solder having an additive that decreases undercooling to provide an increased solidification temperature of the molten solder and reduces formation of the silver compound.

7. The method of claim 1, wherein positioning a solder mask includes positioning a metallic mask on the IC package substrate.

8. The method of claim 1, including arranging an IC on the IC package substrate, wherein the solder bumps provide electrical continuity to connection pads of the IC.

9. The method of claim 8, wherein arranging an IC on the IC package substrate includes arranging the IC on a first IC package substrate and arranging a second IC package substrate above the IC, wherein the method further includes forming solder bumps on both the first and second IC package substrates, wherein the solder bumps include the additive to reduce formation of a silver compound that causes deformation of the solder bumps.

10. An apparatus comprising:
an IC;
an IC package including a first IC package substrate and the IC bonded to the first IC package substrate; and
a plurality of solder bumps formed on the first IC package substrate to provide electrical continuity to connection pads of the IC, wherein the solder bumps have a pitch spacing of 300 μm or less, and wherein solder of a solder bump includes silver and an additive to reduce formation of a silver compound that causes deformation of the solder bump.

11. The apparatus of claim 10, wherein the solder includes a zinc concentration in a range of 2-5 wt % as the additive to reduce formation of a silver compound.

12. The apparatus of claim 11, wherein the solder includes an iron concentration of 3 wt % as the additive to reduce formation of a silver compound.

13. The apparatus of claim 10, wherein the solder includes a nucleation agent as the additive to reduce formation of a silver compound.

14. The apparatus of claim 10, wherein the solder includes tin and an additive to reduce formation of a silver-tin compound.

15. The apparatus of claim 10, wherein the solder includes an additive that increases a solidifying temperature of molten solder and reduces formation of a silver compound during cooling of the molten solder.

16. The apparatus of claim 10, including a second IC package substrate, wherein the IC is bonded to a top surface of the first IC package substrate and a bottom surface of the second IC package substrate, and wherein the plurality of solder bumps are arranged on a bottom surface of the first IC package substrate and a top surface of the second IC package substrate.

17. A system comprising:
an IC;
a printed circuit board (PCB); and
an IC package including an IC package substrate, wherein the IC is bonded to the IC package substrate and the IC package substrate is bonded to the PCB using a plurality of solder connections, wherein the solder connections have a pitch spacing of 300 μm or less, wherein solder of a solder connection includes silver and an additive to reduce formation of a silver compound that causes deformation of the solder bump.

18. The system of claim 17, wherein the solder includes zinc as the additive to reduce formation of a silver compound.

19. The system of claim 17, wherein the solder includes a nucleating agent as the additive to reduce formation of a silver compound.

20. The system of claim 17, wherein the solder includes an additive that decreases undercooling to provide an increased solidification temperature of the molten solder and reduces formation of the silver compound.
